(19) United States
(12) Patent Application Publication
(10) Pub. No.: US 2012/0064462 A1
(43) Pub. Date: Mar. 15, 2012

(54) BY-PRODUCT MITIGATION IN THROUGH-SILICON-VIA PLATING

(76) Inventors: Mark J. WILLEY, Portland, OR (US); Hyosang LEE, Tigard, OR (US)

(21) Appl. No.: 13/229,615

(22) Filed: Sep. 9, 2011

Related U.S. Application Data
(60) Provisional application No. 61/438,919, filed on Feb. 2, 2011.
(60) Provisional application No. 61/381,404, filed on Sep. 9, 2010.

(51) Int. Cl. C25D 3/38; G03F 7/20; C25B 15/02; C25D 5/54; C25D 5/34

(52) U.S. Cl. 430/325; 205/261; 205/159; 205/291; 205/210; 204/229.4

(57) ABSTRACT

Methods, systems, and apparatus for plating a metal onto a work piece with a plating solution having a low oxygen concentration are described. In one aspect, a method includes reducing an oxygen concentration of a plating solution. The plating solution includes about 10 parts per million or less of an accelerator and about 300 parts per million or less of a suppressor. After reducing the oxygen concentration of the plating solution, a wafer substrate is contacted with the plating solution in a plating cell. The oxygen concentration of the plating solution in the plating cell is about 1 part per million or less. A metal is then electroplated onto the wafer substrate in the plating cell.

### CROSS-REFERENCE TO RELATED APPLICATIONS

This application claims benefit under 35 U.S.C. §119(e) to U.S. Provisional Patent Application No. 61/381,404, filed Sep. 9, 2010, and to U.S. Provisional Patent Application No. 61/438,919, filed Feb. 2, 2011, both of which are herein incorporated by reference.

### BACKGROUND

Damascene processing is a method for forming metal lines on integrated circuits. It is often used because it requires fewer processing steps than other methods and offers a high yield. Through-silicon-vias (TSVs) are sometimes used in conjunction with Damascene processing to create three-dimensional (3D) packages and 3D integrated circuits by providing interconnection of vertically aligned electronic devices through internal wiring. Such 3D packages and 3D integrated circuits may significantly reduce the complexity and overall dimensions of a multi-chip electronic circuit. Conductive routes on the surface of an integrated circuit formed during Damascene processing or in TSVs are commonly filled with copper.

### SUMMARY

Methods, apparatus, and systems for plating metals are provided. According to various implementations, the methods involve reducing the oxygen concentration in a plating solution, contacting a wafer substrate with the plating solution, and electroplating a metal onto the wafer substrate.

According to one implementation, a method of electroplating a metal onto a wafer substrate includes reducing an oxygen concentration of a plating solution. The plating solution includes about 10 parts per million or less of an accelerator and about 300 parts per million or less of a suppressor. After reducing the oxygen concentration of the plating solution, a wafer substrate in a plating cell is contacted with the plating solution, with the oxygen concentration of the plating solution in the plating cell being about 1 part per million or less. A metal is then electroplated onto the wafer substrate in the plating cell.

According to one implementation, a solution includes a metal salt, about 1 part per million or less of oxygen, about 10 parts per million or less of an accelerator, and about 300 parts per million or less of a suppressor. The solution may be a plating solution or the solution may be a pre-wetting solution.

According to one implementation, an apparatus for electroplating a metal includes a plating cell and a controller. The controller includes program instructions for conducting a process including the operations of: 1) reducing an oxygen concentration of a plating solution including about 10 parts per million or less of an accelerator and about 300 parts per million or less of a suppressor; 2) after reducing the oxygen concentration of the plating solution, contacting a wafer substrate in a plating cell with the plating solution, with the oxygen concentration of the plating solution in the plating cell being about 1 part per million or less; and 3) electroplating a metal onto the wafer substrate in the plating cell.

According to one implementation, a non-transitory computer machine-readable medium comprising program instructions for control of a deposition apparatus includes code for: 1) reducing an oxygen concentration of a plating solution including about 10 parts per million or less of an accelerator and about 300 parts per million or less of a suppressor; 2) after reducing the oxygen concentration of the plating solution, contacting a wafer substrate in a plating cell with the plating solution, with the oxygen concentration of the plating solution in the plating cell being about 1 part per million or less; and 3) electroplating a metal onto the wafer substrate in the plating cell.

These and other aspects of implementations of the subject matter described in this specification are set forth in the accompanying drawings and the description below.

### BRIEF DESCRIPTION OF THE DRAWINGS

FIG. 1 shows an example of a method of electroplating a metal onto a wafer substrate.

FIG. 2 shows an example of a schematic illustration of an apparatus configured to perform the methods disclosed herein.

FIG. 3 shows an example of a schematic illustration of an electrofill system.

### DETAILED DESCRIPTION

In the following detailed description, numerous specific implementations are set forth in order to provide a thorough understanding of the disclosed implementations. However, as will be apparent to those of ordinary skill in the art, the disclosed implementations may be practiced without these specific details or by using alternate elements or processes. In other instances well-known processes, procedures, and components have not been described in detail so as not to unnecessarily obscure aspects of the present invention.

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. The following detailed description assumes the invention is implemented on a wafer. However, the invention is not so limited. The work piece may be of various shapes, sizes, and materials. In addition to semiconductor wafers, other work pieces that may take advantage of this invention include various articles such as printed circuit boards and the like.

Some implementations described herein relate to methods, apparatus, and systems for plating a metal in features of a wafer substrate. The disclosed methods are particularly applicable for plating copper in high aspect ratio (greater than about 10:1) through-silicon-via (TSV) features with at least about a 5 micrometer diameter via opening. TSV structures are further described in U.S. Pat. No. 7,776,741, which is herein incorporated by reference. In implementations of the disclosed methods, the plating solution used to electroplate copper may have an oxygen concentration of less than about 3 parts per million in the plating cell, and generally less than about 1 part per million. The plating solution may also include an accelerator in a concentration of about 10 parts per million or less and a suppressor in a concentration of about 300 parts per million or less.

Introduction

Plating solutions may contain a number of additives, including accelerators, suppressors, and levelers. Accelerators, alternatively termed brighteners, are additives which increase the rate of the plating reaction. Accelerators are molecules which adsorb on metal surfaces and increase the local current density at a given applied voltage. Accelerators may contain pendant sulfur atoms, which are understood to participate in the cupric ion reduction reaction and thus strongly influence the nucleation and surface growth of metal films. Accelerator additives are commonly derivatives of mercaptopropanesulfonic acid (MPS), dimercaptopropanesulfonic acid (DPS), or bis (3-sulfopropyl) disulfide (SPS), although other compounds can be used. Non-limiting examples of deposition accelerators include the following: 2-mercaptoethane-sulfonic acid (MESA), 3-mercapto-2-propane sulfonic acid (MPSA), dimercaptopropionylsulfonic acid (DMPSA), dimercaptoethane sulfonic acid (DMESA), 3-mercaptopropionic acid, mercaptopyruvate, 3-mercapto-2-butanol, and 1-thioglycerol. Some useful accelerators are described, for example, in U.S. Pat. No. 5,252,196, which is herein incorporated by reference. Accelerators are available commercially as Ultrafill A-2001 from Shipley (Marlborough, Mass.) or as SC Primary from Enthone Inc. (West Haven, Conn.), for example.

Suppressors are polymers that tend to suppress current after they adsorb onto the metal surface. Suppressors may be derived from polyethylene glycol (PEG), polypropylene glycol (PPG), polyethylene oxide, or their derivatives or co-polymers. Commercial suppressors include Ultrafill S-2001 from Shipley (Marlborough, Mass.) and 5200 from Enthone Inc. (West Haven, Conn.), for example. Levelers generally may be cationic surfactants and dyes which suppress current at locations where their mass transfer rate are most rapid. The presence of levelers, therefore, in a plating solution serve to reduce the film growth rate at protruding surfaces or corners where the levelers are preferentially absorbed. Absorption differences of levelers due to differential mass transfer effects may have a significant effect. Accelerators, suppressors, and levels are further described in U.S. Pat. No. 6,793,796, which is herein incorporated by reference.

A balance between the effects of the plating solution additives, particularly the accelerator and the suppressor, may be maintained in the plating solution when filling TSV features with a metal. Suppressors may act to suppress metal plating in the field regions of a wafer substrate, but not in the TSV features. Accelerators may accelerate metal plating in the regions of high current density on the wafer substrate; regions of high current density on a wafer substrate may include TSV features.

Electroplating a metal in Damascene features on a wafer substrate may be completed on the order of about one second. Thus, when filling Damascene features, there may be little time in which the balance between the effects of the accelerator and the suppressor may be disturbed. In contrast, electroplating a metal in a TSV feature on a wafer substrate may take on the order of about 30 minutes or longer. The plating time for the TSV features may depend upon both the diameter of the via and the depth of the via, and may increase with increases in the diameter and/or the depth of the via. It may be difficult to maintain the balance between the effects of the accelerator and the suppressor over these longer times required to fill TSV features. As a consequence, a different additive profile may be used for TSV plating compared to Damascene plating. Notably, a lower concentration of accelerator may be used for TSV plating.

While counterintuitive, low accelerator concentrations can provide advantages, particularly for TSV applications, as they allow for reduced accelerator accumulation on the field regions on the wafer substrate surface while still driving bottom up fill in the TSV features over long periods of electrofilling. This is especially true for high aspect ratio features where the aspect ratio is greater than about 10:1 and the diameter of the feature opening is about 5 micrometers or greater. It may be important to maintain longtime suppression on the field region of a wafer substrate surface that includes TSVs, as the longtime suppression may allow the fill to be driven in the TSVs. If the field regions on the wafer substrate surface are accelerated (or not suppressed), then current that could aid in plating metal in the TSVs may instead go towards depositing metal in the field region and decrease the plating speed of the TSVs. Further, not maintaining longtime suppression on the field region of a wafer substrate surface may lead to the formation of voids in the TSVs, which is undesirable.

Current TSV plating in low accelerator concentration (e.g., less than about 10 parts per million (ppm)) plating solutions, however, may not be possible due to the buildup of by-products from the accelerator. For comparison, Damascene plating may be performed in high accelerator concentration (e.g., about 10 to 50 ppm) plating solutions, which have been found unsuitable for TSV applications. The by-products associated with low accelerator concentration plating solutions cause the field region of the wafer to become overly accelerated as plating progresses. This in turn may cause problems with the fill of deep features (e.g., TSV features) as the suppression gradient that drives the fill of the features is lost (i.e., field suppression may be continually lost as accelerator by-products build up on field).

Oxygen dissolved in the plating solution may be at least partially responsible for creating these troublesome by-products. A discussion of the by-products produced in a specific plating bath is found in “Bis-(3-sodiumsulfopropyl disulfide) Decomposition with Cathodic Current Flowing in a Copper-Electroplating Bath,” J. Electrochem. Soc., Volume 157, Issue 1, pp. H131-H135 (2010), by Wen-Hsi Lee, Chi-Cheng Hung, Shih-Chieh Chang, and Ying-Lang Wang, which is herein incorporated by reference. A proposed reaction mechanism for the breakdown of a specific accelerator, bis (3-sulfopropyl) disulfide (SPS), is given in “Invalidating mechanism of bis (3-sulfopropyl) disulfide (SPS) during copper via-filling process,” Applied Surface Science, Volume 255, Issue 8, 1 Feb. 2009, Pages 4389-4392, by Wei Wang, Ya-Bing Li, and Yong-Lei Li, which is herein incorporated by reference.

For example, when using dimercaptopropanesulfonic acid (DPS) based accelerators, an equilibrium exists between mercaptopropanesulfonic acid (MPS) and its dimer, bis (3-sulfopropyl) disulfide (SPS), in the plating solution. Two molecules of MPS may combine to form SPS, and the SPS may split to form two molecules of MPS. When an MPS molecule is oxidized, however, it is not able to reform a dimer. It is believed that the oxidized MPS molecules tend to aggregate on the field regions of the wafer substrate, where they are continually available to accelerate metal deposition. These oxidized MPS molecules may disrupt the balance between the accelerator and the suppressor and overwhelm the effect of the suppressor in the field region of the wafer substrate. This can be a particular problem in TSV plating where electrofilling occurs for long periods of time, e.g., on the order of tens of minutes.

Thus, for sustained plating in low accelerator concentration plating solutions, the amount of oxygen in the plating solution may be limited in order to stabilize the plating solution. When oxygen is in a plating solution, the accelerator may oxidize over time with the passage of charge though the plating solution. Specifically, during the electroplating of copper, low plating currents may generate stable cuprous ions on the wafer substrate. The cuprous ions may react with the accelerator and may form a catalyst that promotes the formation of oxidized accelerator by-products. Disclosed implementations may allow for the stabilization of the plating solution and therefore the prolonged plating of deep features due to the minimization of oxidized accelerator by-products generated from reactions between the accelerator and oxygen. In addition to providing stable plating solutions, disclosed implementations may also decrease the cost of consumables used for an electroplating apparatus as the degradation of the accelerator may be limited.

Method

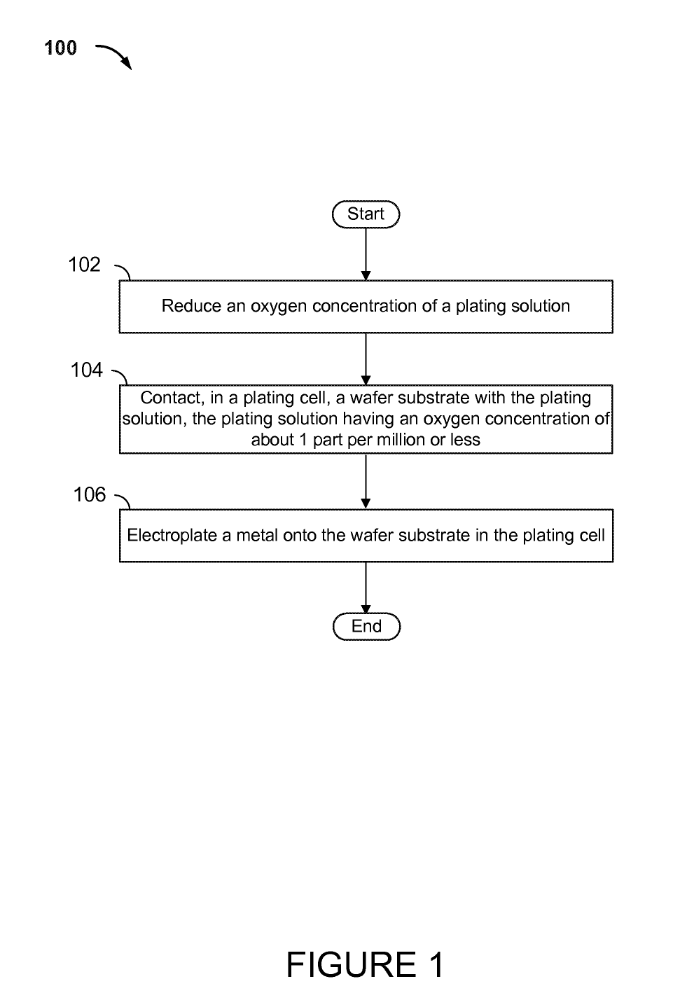

FIG. 1 shows an example of a method of electroplating a metal onto a wafer substrate. Starting at block 102 of the method 100, the oxygen concentration of a plating solution is reduced.

The oxygen concentration in the plating solution may be due to oxygen in the atmosphere, and may be about 8 to 10 ppm, depending on atmospheric pressure. This oxygen concentration in the plating solution is believed to increase the rate of by-product formation from the accelerator (sometimes producing concentrations of the by-products of about 10 to 1000 parts per billion (ppb)). These by-products may change the metal deposition characteristics over time as charge is passed through the plating solution and the accelerator breaks down, as explained above. In some implementations, to reduce or eliminate the formation of these by-products, before the wafer substrate is placed into contact with a plating solution contained in the plating cell, the oxygen concentration level of the plating solution may be reduced.

In some implementations, the plating solution may be supplied to the plating cell from an external reservoir or compartment. In some implementations, the oxygen concentration may be maintained at different concentrations in the plating cell (where the electroplating takes place) and the compartment. For example, when the oxygen concentration in the plating solution is less than about 1 ppm in the plating cell, the oxygen concentration in the plating solution may be less than about 10 ppm in the compartment. In some implementations, the oxygen concentration of the plating solution in the plating cell may be lower than the oxygen concentration of the plating solution in the compartment because the plating solution may pass through a degassing device immediately before entering the plating cell, as described below.

In some implementations, the plating solution may include about 10 ppm or less of accelerator and about 300 ppm or less of suppressor. In some implementations, the plating solution may include about 5 ppm or less of accelerator, about 1 ppm to 5 ppm of accelerator, about 2 ppm of accelerator, or about 2 ppm or less of accelerator. In some implementations, the plating solution may include about 50 ppm to 200 ppm of suppressor or about 200 ppm to 250 ppm of suppressor. Generally, the upper range of suppressor concentration is the concentration at with the suppressor saturates the field region. Under a range process conditions, suppressor concentrations of about 200 ppm or higher may saturate the field regions of the wafer substrate with suppressor while allowing a reduced amount of suppressor in the feature.

In implementations where copper is the metal that is plated on the wafer substrate, the plating solution contains copper at the concentrations of about 20 to 100 grams per liter, or about 40 to 80 grams per liter. In some implementations, the plating solution may contain copper at a concentration of about 80 grams per liter.

In some implementations, the plating solution includes substantially no leveler. Levelers also may degrade with extended plating times, which may hinder the plating process and cause fill problems.

At block 104, a wafer substrate is contacted with the plating solution in a plating cell. In some implementations, the oxygen concentration of the plating solution in the plating cell is about 1 part per million or less. In some implementations, the oxygen concentration of the plating solution in the plating cell may be about 100 parts per billion (ppb) or less or there may be substantially no oxygen may in the plating solution. In some other implementations, the oxygen concentration of the plating solution in the plating cell may be about 5 ppm or less or about 3 ppm or less.

At block 106, a metal is electroplated onto the wafer substrate in the plating cell. Electrical power, which may be provided by controlling current and/or potential, may be applied to the wafer substrate to deposit the metal. In some implementations, the electroplating takes place for about 1 minute to 5 hours. In some other implementations, the electroplating takes place for about at least about 10 minutes or about 10 minutes to 3 hours. In some implementations, the metal may be electroplated onto a TSV of the wafer substrate. In some other implementations, the metal may be electroplated onto a wafer substrate level packaging feature of the wafer substrate.

The method 100 shown in FIG. 1 may also include a pre-wetting operation, in some implementations. For example, the wafer substrate may be pre-wetted before the wafer substrate is placed in contact with the plating solution, in some implementations. A pre-wetting process may overcome the deleterious effects of gaseous bubbles that may become trapped in features on a wafer substrate when the wafer substrate is contacted with the plating solution. One example of a pre-wetting process includes: 1) rotating the wafer substrate at a first rotation rate; and, 2) forming a wetting layer on the wafer substrate at sub-atmospheric pressure by contacting the wafer substrate with a degassed pre-wetting fluid while rotating the wafer substrate at the first rotation rate, the degassed pre-wetting fluid being in a liquid state.

In some implementations, the pre-wetting solution may be substantially free of oxygen. In some implementations, the pre-wetting solution may be the same solution as the plating solution. In some other implementations, the pre-wetting solution may not be the same solution as the plating solution. For example, deionized water may be used as the pre-wetting solution. Pre-wetting processes and apparatus for performing pre-wetting processes are describe in further detail in U.S. patent application Ser. No. 12/684,787, titled “WETTING PRETREATMENT FOR ENHANCED DAMASCENE METAL FILLING,” filed Jan. 8, 2010 and U.S. patent application Ser. No. 12/684,792, titled “APPARATUS FOR WETTING PRETREATMENT FOR ENHANCED DAMASCENE METAL FILLING,” filed Jan. 8, 2010, both of which are herein incorporated by reference.

In an experiment to determine the effect of reducing the oxygen concentration in a plating solution, wafer substrates were plated using plating solutions having identical compositions, but with one plating solution being degassed and one plating solution not being degassed. Wafer substrates were plated, a period of time was allowed to elapse, further wafer substrates were plating, and so on. Both plating solutions included about 2 ppm of accelerator, about 100 ppm of suppressor, and about 60 grams per liter of copper. The TSV features in the wafer substrates were about 6 micrometers in diameter and about 60 micrometers deep. The wafer substrates were pre-wetted with deionized water before the plating process, and the wafer substrates were all plated under the same conditions (e.g., the same voltage and current waveforms). The oxygen concentration of the non-degassed plating solution in both the plating bath compartment and the plating cell was about 8 ppm. The oxygen concentration of the degassed plating solution in the plating bath compartment was about 2.5 ppm, and the oxygen concentration of the degassed plating solution in the plating cell was about 1 ppm.

The plating performance of the non-degassed plating solution degraded after less than 24 hours of use, as shown by the plating solution completely filling TSV features when the plating solution was first used, but not completely filling TSV features after about 15 hours of use and about 5 plating operations. In contrast, with the degassed plating solution, the plating solution exhibited no signs of degradation after about 30 days of used and about 1000 plating operations.

### Apparatus

Another aspect of the disclosed implementations is an apparatus configured to accomplish the methods described herein. A suitable apparatus includes hardware for accomplishing the process operations and a system controller having instructions for controlling process operations in accordance with the present invention. Hardware for accomplishing the process operations includes electroplating apparatus. The system controller will generally include one or more memory devices and one or more processors configured to execute the instructions so that the apparatus will perform a method in accordance with the present invention. Machine-readable media containing instructions for controlling process operations in accordance with the present invention may be coupled to the system controller.

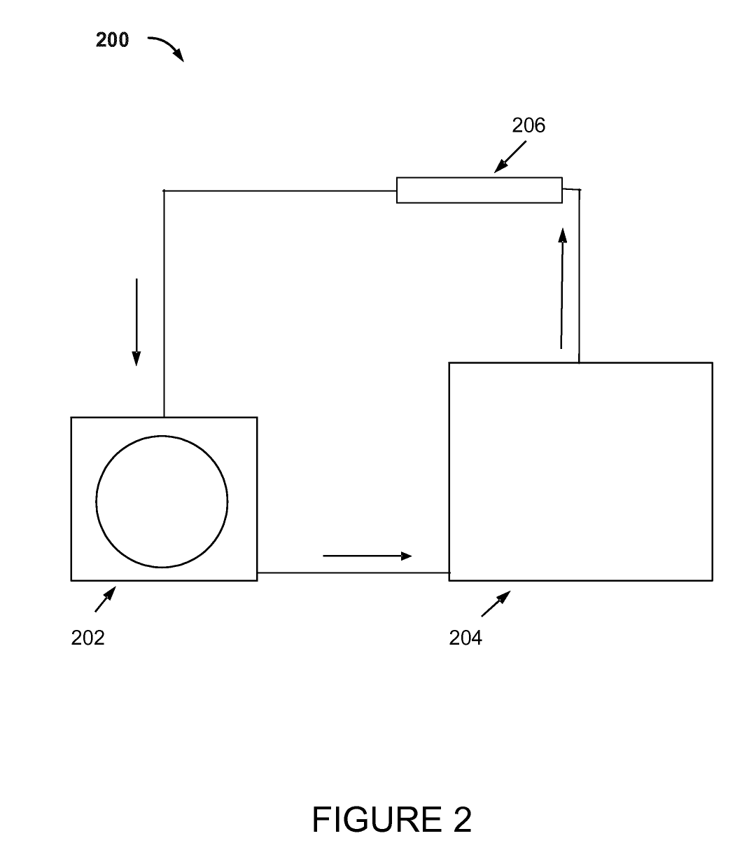

FIG. 2 shows an example of a schematic illustration of an apparatus configured to perform the methods disclosed herein. The apparatus includes a plating cell 202, a plating bath compartment 204, and a degassing device 206. A degassing device may also be referred to as a degasser or a contactor. The arrows associated with the apparatus 200 indicate the flow of the plating solution in the apparatus. The apparatus 200 may further include various valves, vacuum pumps, and other hardware (not shown). When the apparatus 200 is in operation, the plating solution may flow from the plating bath compartment 204, through the degassing device 206, into the plating cell 202, and then back to the plating bath compartment 204.

Before the plating solution enters the plating cell 202 from the plating bath compartment 204, the plating solution passes through the degassing device 206. The degassing device 206 removes one or more dissolved gasses (e.g., both O₂ and N₂) from the plating solution. In some implementations, the degassing device is a membrane contact degasser. Examples of commercially available degassing devices include the Liquid-Cel™ from Membrana (Charlotte, N.C.) and the pHasor™ from Entegris (Chaska, Minn.). The amount of dissolved gas in the plating solution can be monitored with appropriate meters (e.g., a commercial dissolved oxygen meter (not shown)) located in the plating cell and/or in the plating bath compartment.

In some implementations, the volume of the plating bath compartment is purged of gasses by applying a vacuum to the compartment using a vacuum pump (not shown) so that a minimum amount of dissolved gas is achieved. The rate or removal of the gas from the plating solution can also be increased by increasing the exposed surface of the fluid to the vacuum, for example, by having the fluid re-enter the plating bath compartment from the circulation loop in a spray or through a spray column.

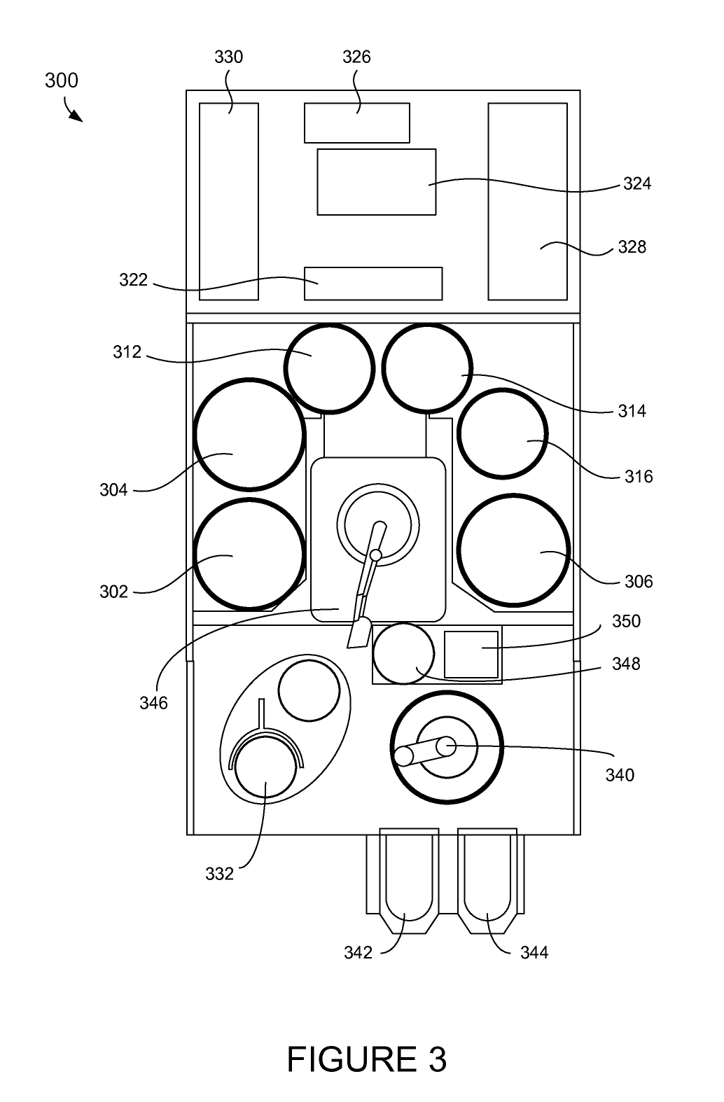

FIG. 3 shows an example of a schematic illustration of an electrofill system 300. The electrofill system 300 includes three separate electrofill modules 302, 304, and 306. The electrofill system 300 also includes three separate post electrofill modules (PEMs) 312, 314, and 316 configured for various process operations. The modules 312, 314, and 316 may be post electrofill modules (PEMs) each configured to perform a function, such as edge bevel removal, backside etching, and acid cleaning of wafers after they have been processed by one of the electrofill modules 302, 304, and 306.

The electrofill system 300 includes a central electrofill chamber 324. The central electrofill chamber 324 is a chamber that holds the chemical solution used as the plating solution in the electrofill modules. The electrofill system 300 also includes a dosing system 326 that may store and deliver chemical additives for the plating solution. A chemical dilution module 322 may store and mix chemicals to be used as an etchant, for example, in a PEM. A filtration and pumping unit 328 may filter the plating solution for the central electrofill chamber 324 and pump it to the electrofill modules. The system also includes a degassing device or degassing devices (not shown), as described above. The plating solution may pass through the degassing device before in is pumped to the electroplating modules.

A system controller 330 provides the electronic and interface controls required to operate the electrofill system 300. The system controller 330 generally includes one or more memory devices and one or more processors configured to execute instructions so that the apparatus can perform a method in accordance with the implementations described herein. Machine-readable media containing instructions for controlling process operations in accordance with the implementations described herein may be coupled to the system controller. The system controller 330 may also include a power supply for the electrofill system 300. An example of an electroplating module and associated components is shown in U.S. patent application Ser. No. 12/786,329, entitled “PULSE SEQUENCE FOR PLATING ON THIN SEED LAYERS,” filed May 24, 2010, which is herein incorporated by reference.

In operation, a hand-off tool 340 may select a wafer from a wafer cassette such as the cassette 342 or the cassette 344, The cassettes 342 or 344 may be front opening unified pods (FOUPs). A FOUP is an enclosure designed to hold wafers securely and safely in a controlled environment and to allow the wafers to be removed for processing or measurement by tools equipped with appropriate load ports and robotic handling systems. The hand-off tool 340 may hold the wafer using a vacuum attachment or some other attaching mechanism.

The hand-off tool 340 may interface with an annealing station 332, the cassettes 342 or 344, a transfer station 350, or an aligner 348. From the transfer station 350, a hand-off tool 346 may gain access to the wafer. The transfer station 350 may be a slot or a position from and to which hand-off tools 340 and 346 may pass wafers without going through the aligner 348. In some implementations, however, to ensure that a wafer is properly aligned on the hand-off tool 346 for precision delivery to an electrofill module, the hand-off tool 346 may align the wafer with an aligner 348. The hand-off tool 346 may also deliver a wafer to one of the electrofill modules 302, 304, or 306 or to one of the three separate modules 312, 314, and 316 configured for various process operations.

For example, the hand-off tool 346 may deliver the wafer substrate to the electrofill module 302 where a metal (e.g., copper) is plated onto the wafer substrate in accordance with implementations described herein. After the electroplating operation completes, the hand-off tool 346 may remove the wafer substrate from the electrofill module 302 and transport it to one of the PEMs, such as PEM 312. The PEM may clean, rinse, and/or dry the wafer substrate. Thereafter, the hand-off tool 346 may move the wafer substrate to another one of the PEMs, such as PEM 314. There, unwanted metal (e.g., copper) from some locations on the wafer substrate (e.g., the edge bevel region and the backside) may etched away by an etchant solution provided by chemical dilution module 322. The module 314 may also clean, rinse, and/or dry the wafer substrate.

After processing in the electrofill modules and/or the PEMs is complete, the hand-off tool 346 may retrieve the wafer from a module and return it to the cassette 342 or the cassette 344. A post electrofill anneal may be completed in the electrofill system 300 or in another tool. In one implementation, the post electrofill anneal is completed in one of the anneal stations 332. In some other implementations, dedicated annealing systems such as a furnace may be used. Then the cassettes can be provided to other systems such as a chemical mechanical polishing system for further processing.

Suitable semiconductor processing tools include the Sabre System and the Sabre System 3D Lite manufactured by Novellus Systems of San Jose, Calif., the Slim cell system manufactured by Applied Materials of Santa Clara, Calif., or the Raider tool manufactured by Semitool of Kalispell, Mont.

The methods and apparatus described herein provide particular advantage when plating substrates having relatively large features. It should be understood that these plating conditions and apparatus are not limited to TSV applications. For example, reduced oxygen plating solutions may be used in wafer level packaging applications as well, to plate, e.g., copper redistribution lines, pillars, bumps, etc.

### Further Implementations

The apparatus/methods described hereinabove may be used in conjunction with lithographic patterning tools or processes, for example, for the fabrication or manufacture of semiconductor devices, displays, LEDs, photovoltaic panels and the like. Generally, though not necessarily, such tools/processes will be used or conducted together in a common fabrication facility. Lithographic patterning of a film generally comprises some or all of the following steps, each step enabled with a number of possible tools: (1) application of photoresist on a workpiece, i.e., a substrate, using a spin-on or spray-on tool; (2) curing of photoresist using a hot plate or furnace or UV curing tool; (3) exposing the photoresist to visible, UV, or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

It should also be noted that there are many alternative ways of implementing the disclosed methods and apparatuses. It is therefore intended that the following appended claims be interpreted as including all such alterations, modifications, permutations, and substitute equivalents as fall within the true spirit and scope of implementations of the present invention.

What is claimed is:

1. A method comprising:
reducing an oxygen concentration of a plating solution, wherein the plating solution includes about 10 parts per million or less of an accelerator and about 300 parts per million or less of a suppressor;
after reducing the oxygen concentration of the plating solution, contacting, in a plating cell, a wafer substrate with the plating solution, wherein the oxygen concentration of the plating solution in the plating cell is about 1 part per million or less; and
electroplating a metal onto the wafer substrate in the plating cell.

2. The method of claim 1, wherein the plating solution includes about 5 parts per million or less of the accelerator

3. The method of claim 1, wherein the wafer substrate comprises at least one feature having an aspect ratio of at least about 10:1 and an opening diameter or width of at least about a 5 micrometers.

4. The method of claim 1, wherein the electroplating takes place for at least about 10 minutes

5. The method of claim 1, wherein the metal is electroplated onto a through-silicon-via.

6. The method of claim 1, wherein the metal is electroplated onto a wafer substrate level packaging feature.

7. The method of claim 1, further comprising:
supplying the plating solution to the plating cell from a plating compartment, wherein the oxygen concentration of the plating solution in the plating compartment is less than about 10 parts per million, and wherein reducing the oxygen concentration of the plating solution is performed as the plating solution is supplied from the plating compartment.

8. The method of claim 1, wherein the plating solution includes substantially no leveler.

9. The method of claim 1, wherein the metal includes copper.

10. The method of claim 1, wherein the plating solution includes about 40 to 80 grams per liter of copper.

11. The method of claim 1, further comprising:
pre-wetting the wafer substrate before contacting the wafer substrate with the plating solution.

12. The method of claim 11, wherein the wafer substrate is pre-wetted with the plating solution.

13. The method of claim 1, wherein reducing the oxygen concentration of the plating solution is performed with a degassing device.

14. The method of claim 1, further comprising:
applying photoresist to the wafer substrate;
exposing the photoresist to light;
patterning the resist and transferring the pattern to the wafer substrate; and
selectively removing the photoresist from the wafer substrate.

15. A solution comprising:
a metal salt;
about 1 part per million or less of oxygen;
about 10 parts per million or less of an accelerator; and
about 300 parts per million or less of a suppressor.

16. The solution of claim 15, wherein the solution is a plating solution.

17. The solution of claim 15, wherein the solution is a pre-wetting solution.

18. An apparatus for electroplating a metal, comprising:
(a) a plating cell; and
(b) a controller comprising program instructions for conducting a process comprising the steps of:
reducing an oxygen concentration of a plating solution, wherein the plating solution includes about 10 parts per million or less of an accelerator and about 300 parts per million or less of a suppressor;
after reducing the oxygen concentration of the plating solution, contacting, in a plating cell, a wafer substrate with the plating solution, wherein the oxygen concentration of the plating solution in the plating cell is about 1 part per million or less; and
electroplating a metal onto the wafer substrate in the plating cell.

19. A system comprising the apparatus of claim 18 and a stepper.

20. A non-transitory computer machine-readable medium comprising program instructions for control of an apparatus, the instructions comprising code for:
reducing an oxygen concentration of a plating solution, wherein the plating solution includes about 10 parts per million or less of an accelerator and about 300 parts per million or less of a suppressor;
after reducing the oxygen concentration of the plating solution, contacting, in a plating cell, a wafer substrate with the plating solution, wherein the oxygen concentration of the plating solution in the plating cell is about 1 part per million or less; and
electroplating a metal onto the wafer substrate in the plating cell.
